(19) United States
(12) Patent Application Publication
(10) Pub. No.: US 2010/0064196 A1
(43) Pub. Date: Mar. 11, 2010

(54) DATA PROCESSING SYSTEMS AND METHODS FOR LOADING DATA FROM NON VOLATILE MEMORY TO A MEMORY

(75) Inventors: Kuan-Yuan Tseng, Taipei City (TW); Ming-Jen Lee, Taipei City (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: ASUSTEK COMPUTER INC., Taipei City (TW)

(21) Appl. No.: 12/540,480

(22) Filed: Aug. 13, 2009

(30) Foreign Application Priority Data
Sep. 10, 2008 (TW) 97134645

(51) Int. Cl. H03M 13/00; G06F 11/08

(52) U.S. Cl. 714/752; 714/E11.02; 714/E11.03; 713/2

(57) ABSTRACT

A data processing method for loading data from a non volatile memory to a memory is disclosed. A template data and a data block corresponding thereto in the non volatile memory are loaded to a buffer. A reference value of the template data and a corresponding reference value of the data block are compared to determine whether the reference value and the corresponding reference value are matched. If not, a modification algorithm is performed to adjust the data format of the loaded data block based on the reference value of the template data. Then, system related information is generated and stored to the memory according to data in the template data and the adjusted data block in the buffer.

### CROSS REFERENCE TO RELATED APPLICATIONS

This Application claims priority of Taiwan Patent Application No. 097134645, filed on Sep. 10, 2008, the entirety of which is incorporated by reference herein.

### BACKGROUND OF THE INVENTION

1 Field of the Invention

The invention relates to a processing apparatus and data processing method thereof, and more particularly, to a non volatile memory data processing method for correcting data with different data formats therein.

2. Description of the Related Art

In computer systems, all information are recorded in a non volatile memory that has a basic input/output system (BIOS). System Management BIOS (hereinafter referred to as SMBIOS) is one commonly used BIOS format in which the SMBIOS specification defines information regarding data structures or types of system hardware and methods to acquire hardware information. The SMBIOS records hundreds of kinds of configurations such as part numbers, BIOS versions and manufacturing dates, motherboard vendors, motherboard serial numbers, CPU types, memory sizes and so on. The SMBIOS is an extension of the BIOS which is capable of organizing and delivering BIOS messages to the operating system. In other words, the SMBIOS addresses how motherboard and system vendors may present management information about their products in a standard format.

After a computer system is initiated and initial configurations have been completed, a BIOS procedure is activated. The BIOS writes system hardware related information to a memory according to a standard format specified in the SMBIOS. Following, system related information may be acquired by using the standard format specified in the SMBIOS.

Generally, the main BIOS area in a non volatile memory (e.g. a read-only BIOS memory) stores template data and a data block which corresponds to the template data, generated according to the standard format specified in the SMBIOS. However, if the BIOS is being updated and the format of the template data in the BIOS and the format of the SMBIOS data block do not match, data content in the SMBIOS data block may be erroneously interpreted and thus system information of the BIOS may contain incorrect values or be misinterpreted. For example, comparing to old SMBIOS version V2.3 and the new SMBIOS version V2.4, additional strings have been added to the new format and thus interpretation of the data content in the SMBIOS data block may be incorrect if the data content whose data format uses old SMBIOS version V2.3 is interpreted by the new format for the SMBIOS version V2.4.

Thus, generally, before updating the BIOS, the original SMBIOS strings will be read and temporarily stored in the memory, then all of the content of the BIOS will be erased and an the updated SMBIOS strings will be written back to the BIOS.

However, if an error occurs during a BIOS updating procedure (such as power lost), original backup data (e.g. motherboard serial number) may be lost, causing unpredictable errors. Thus, a desktop management interface (DMI) tool program may be used to modify erroneous strings that are being misinterpreted to corresponding correct values. However, this operation must be manually performed, thereby requiring labor and increasing set up time, which raises costs and is not easy for use in a production line.

### BRIEF SUMMARY OF THE INVENTION

Processing apparatuses and data processing methods for loading data from a non volatile memory to a memory are provided to solve the aforementioned problems caused by data format inconsistencies.

The data processing method comprises the following steps. A template data in the non volatile memory is first loaded to a buffer and then a data block corresponding to the template data in the non volatile memory is loaded. It is compared whether a first reference value of the template data matches to a second reference value of the data block. A modification algorithm is performed to adjust the data format of the loaded data block based on the first reference value of the template data when the first reference value does not match to the second reference value. Then, system related information is generated and stored to the memory according to the template data and the adjusted data block in the buffer.

A processing apparatus is further disclosed. The processing apparatus comprises a non volatile memory, a memory, a loading module, a correction module and a processing unit. The non volatile memory has a template data and a data block corresponding to the template data. The loading module loads the template data and the data block from the non volatile memory to a buffer. The correction module compares whether a reference value of the template data matches to a corresponding reference value of the data block and performs a modification algorithm to adjust the data format of the loaded data block based on the first reference value of the template data when the reference value does not match to the corresponding reference value. The processing unit generates system related information and storing the system related information to the memory according to the template data and the adjusted data block in the buffer.

Data processing methods and processing apparatuses may take the form of a program code embodied in a tangible media. When the program code is loaded to and executed by a machine, the machine becomes an apparatus for practicing the disclosed method.

### BRIEF DESCRIPTION OF THE DRAWINGS

The invention can be more fully understood by reading the subsequent detailed description and examples with reference to the accompanying drawings, wherein:

FIG. 1 shows a block diagram of an embodiment of a processing apparatus according to the invention;

FIG. 2 is a flowchart showing an embodiment of a data processing method according to the invention;

FIG. 3 is a flowchart showing another embodiment of a data processing method according to the invention;

FIG. 4 shows an embodiment of the data processing method according to the invention;

FIG. 5 shows an embodiment of a data format according to the invention; and

FIG. 6 is a schematic showing an embodiment of a data format before and after an adjustment according to the invention.

### DETAILED DESCRIPTION OF THE INVENTION

The following description is of the best-contemplated mode of carrying out of the invention. This description is made for the purpose of illustrating the general principles of the invention and should not be taken in a limiting sense. The scope of the invention is best determined by reference to the appended claims.

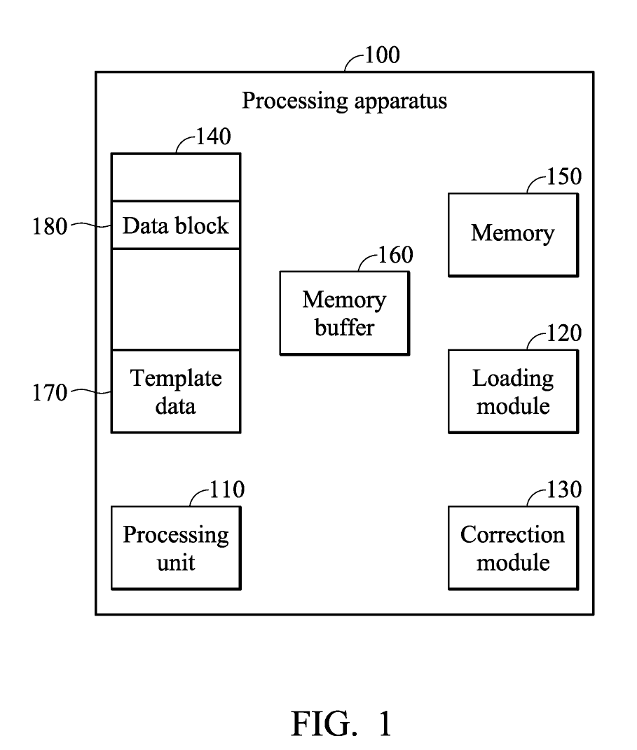

The invention is described with reference to FIGS. 1 through 6, which generally relate to a processing apparatus and data processing method thereof. In the following detailed description, reference is made to the accompanying drawings which from a part hereof, shown by way of illustration of specific embodiments. These embodiments are described in sufficient detail to enable those skilled in the art to practice the invention, and it is to be understood that other embodiments may be utilized and that structural, logical and electrical changes may be made, without departing from the spirit and scope of the invention. The following detailed description is, therefore, not to be taken in a limiting sense. It should be understood that many of the elements described and illustrated throughout the specification are functional in nature and may be embodied in one or more physical entities or may take other forms beyond those described or depicted.

Embodiments of the invention provide a data processing method that is capable of correcting two data formats in a non volatile memory (e.g. a BIOS ROM or a flash memory) that do not match, to match before being loaded to a memory of a processing apparatus (e.g. a dynamic memory) With the data processing method of the invention, when a portion of data is updated, only data in the memory will be updated and not the original data in the non volatile memory, thereby eliminating a need for manually updating data and avoiding data lost caused by failure of the data updating process.

FIG. 1 shows a block diagram of an embodiment of a processing apparatus 100 according to the invention. As shown in FIG. 1, the processing apparatus 100 at least comprises a processing unit 110, a loading module 120, a correction module 130, a non volatile memory 140, a memory 150 and a memory buffer 160. In one embodiment, the non volatile memory 140 may be, for example, a BIOS ROM or a flash memory that is capable of storing data needed for the BIOS procedure.

The non volatile memory 140 at least comprises a template data 170 and a data block 180 corresponding to the template data 170. In one embodiment, the template data 170 may be a template data of the SMBIOS and data in the data block 180 may be the corresponding SMBIOS data.

The loading module 120 is used for loading the template data 170 and the data block 180 in the non volatile memory 140. The correction module 130 is used for comparing whether a reference value of the template data 170 matches to a corresponding reference value of the data block 180 and performing a modification algorithm to adjust the data format of the data block 180 according to the reference value of the template data 170 when the reference value of the template data 170 and the corresponding reference value of the data block 180 are not matched. The processing unit 110 generates system related information according to data in the adjusted data block and the template data and then loads the system related information to the memory 150. The data processing method steps of the invention are detailed below.

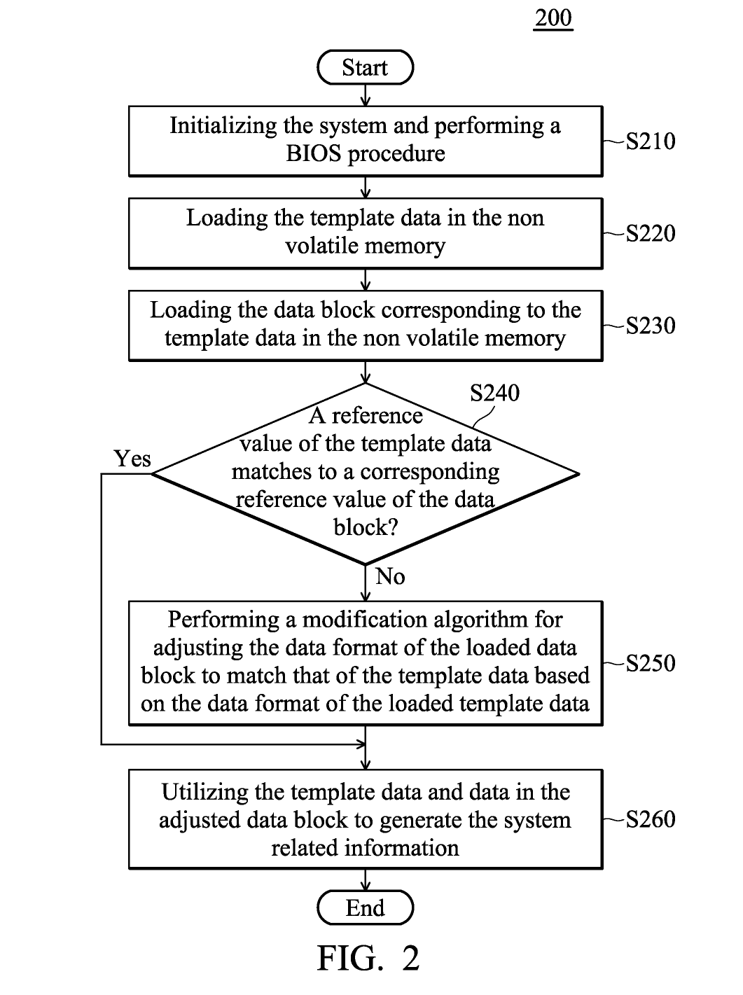

FIG. 2 is a flowchart 200 showing an embodiment of a data processing method according to the invention. Referring to FIG. 1 and FIG. 2, in step S210, the system is initiated and a BIOS procedure is performed. Thereafter, in step S220, the loading module 120 first loads the template data 170 in the non volatile memory 140 and then, in step S230, loads the data block 180 corresponding to the template data 170 in the non volatile memory 140. Note that the template data 170 and the data block 180 are loaded to the memory buffer 160.

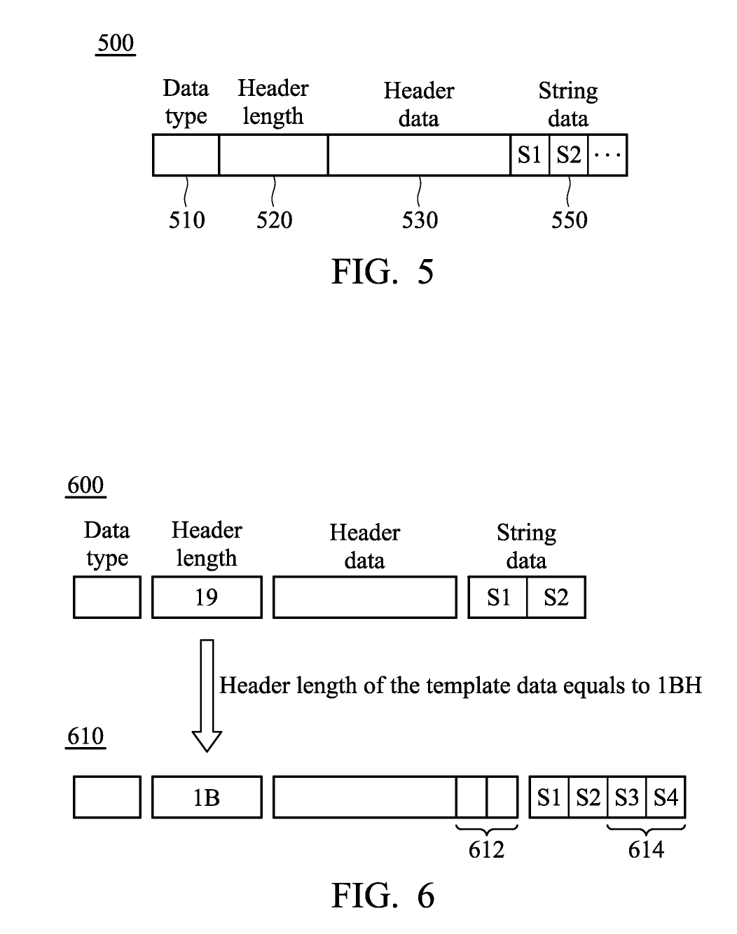

In step S240, the correction module 130 compares whether a reference value of the template data 170 matches to a corresponding reference value of the data block 180. Here the reference value may be a specific item that is the same in both the template data 170 and the data block 180. In one embodiment, a header length may be utilized as the reference value so that the correction module 130 may compare a header length of the template data 170 and a corresponding header length of the data block 180 so as to determine whether the header length of the template data 170 matches to that of the data block 180. The data formats for the template data 170 and the data block 180 are detailed below with reference to FIG. 5.

When the comparison result shows that two data formats are matched (“Yes” in step S240), i.e. the data format of the template data 170 is matched to that of the data block 180, no adjustment is required and thus the system related information may be generated by utilizing the template data 170 and data in the data block 180 (step S260). Contrarily, when the comparison result shows that two data formats are not matched (“No” in step S240), i.e. the data format of the template data 170 is not matched to that of the data block 180, an adjustment is required and thus the correction module 130 will perform a modification algorithm for adjusting the data format of the loaded data block 180 to match that of the template data 170 based on the data format of the loaded template data 170 (Step S250). Therefore, after operation of the modification algorithm has been completed, data in the data block 180 in the memory buffer 160 may be adjusted to a new data format that is the same as the data format of the template data 170. Finally, the processing unit 110 may generate the system related information by utilizing the template data 170 and data in the adjusted data block 180 (step S260).

FIG. 5 shows an embodiment of a data format 500 of the template data according to the invention. As shown in FIG. 5, the data format 500 at least comprises a type field 510, a header length field 520, a header data field 530 and a string data field 550, wherein the type field 510 represents a type of the system data that the data therein represented. For example, type 1 may represent system related information; type 2 may represent motherboard related information and so on. The header length field 520 is used for representing a total length of the type field 510, the header length field 520 and the header data field 530. The string data field 550, which is subsequent to the header data field 530, is used for storing strings that are to be used in the header data field 530, wherein the end of each string is indicated by a specific symbol. For example, the string data field 550 may store the following data ““ABC”,0,“2007/01/01”,0,0”. For example, if the length is in a unit of one byte, value “19 h” in the header length field 530 (where h means hexadecimal representation) represents that the total length of the type field 510, the header length field 520 and the header data field 530 is 25 bytes and the string data field 550 is started from the 26th byte. In other words, if any string is used in the header data filed 530, the required string may be acquired from a position that is the 26 bytes following the header type field 510.

The data block 180 has a data format similar to the data format 500 of the template data 170 except that the string data field 550 of the data format 500 of the template data 170 stores default strings (such as manufacturing default values) while the string data field of the data block 180 stores system related strings. For example, if the manufacturer is “ABC”, the string data field 550 of the template data 170 may store a default string “OEMXXX” while a corresponding string data field of the data block 180 may store the correct string “ABC”. That is, the template data 170 provides a default data format while the data block 180 provides actual content corresponding thereto. Thus, the processing unit 110 must fill the data in the data block 180 to corresponding positions in the template data 170 according to the dedicated data format (e.g. data type and header data). For example, data in the header data field and the string data field whose type is set to be 1 of the data block 180 will be filled into the header data field and the string data field whose type is set to be 1 of the template data 170 so as to acquire the corrected system related information.

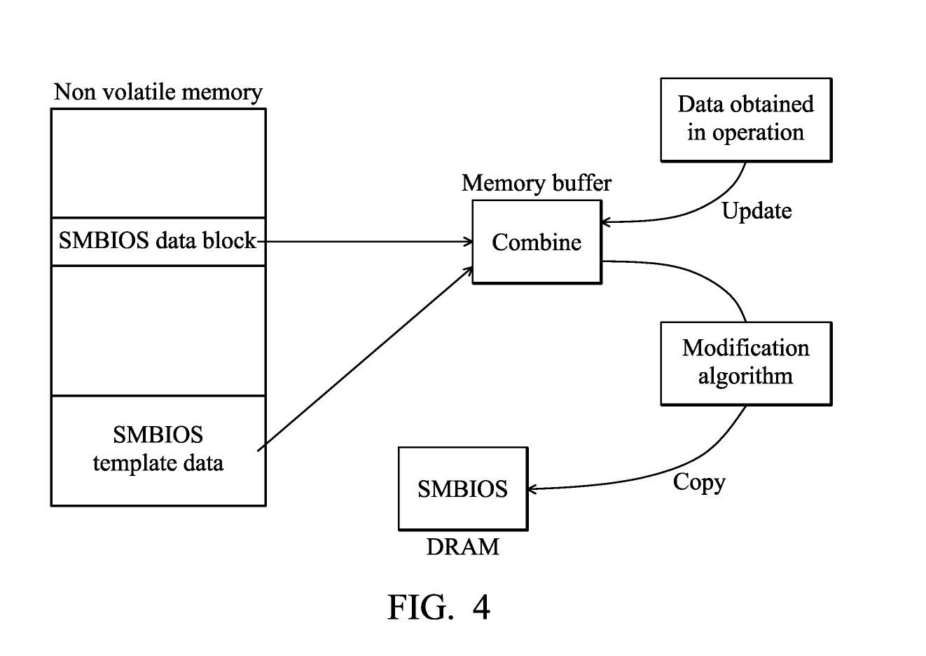

FIG. 4 shows an embodiment of the data processing method according to the invention. In this embodiment, it is assumed that the non volatile memory is a flash memory storing a SMBIOS template data 170 and a corresponding SMBIOS data block 180 in which the same data format 500 is utilized for the SMBIOS template data 170 and the corresponding SMBIOS data block 180. As shown, first, the loading module 120 loads the SMBIOS template data 170 and the corresponding SMBIOS data block 180 in the flash memory to the memory buffer 160. Subsequently, the correction module 130 compares whether a reference value of the template data 170 matches to a corresponding reference value of the data block 180 loaded to the memory buffer 160 and determine whether to perform a modification algorithm for adjusting the data format of the loaded data block based on the comparison result. The processing unit 110 then updates and combines corrected or adjusted data and data collected when performing the modification algorithm (information regarding to speed or frequency of the processing unit) based on the data format defined in the template data 170 and puts the combined data to the corresponding position in the template data 170 until the data combination has been finished. Thereafter, the processing unit 100 loads the combined SMBIOS data to the memory 150 (e.g. a dynamic memory).

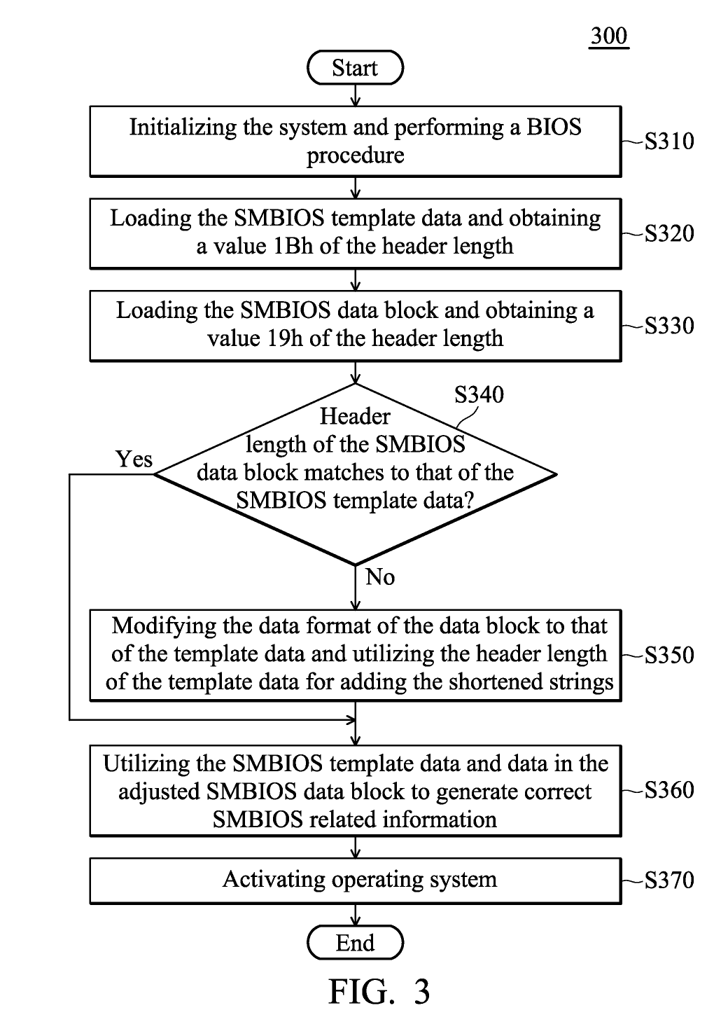

FIG. 3 is a flowchart 300 showing another embodiment of a data processing method according to the invention. In this embodiment, it is assumed that the non volatile memory is a flash memory storing a SMBIOS template data 170 and a corresponding SMBIOS data block 180 in which the same data format 500 is utilized for the SMBIOS template data 170 and the corresponding SMBIOS data block 180. The value of the header length of the type 1 in the SMBIOS data block 180 is set to be 19 h while the value of the header length of the SMBIOS template data 170 is changed to be 1 Bh that is matched to a new format after the BIOS has been updated. It is noted that although only comparison for data with the data type 1 is described, comparisons for other data types may also be applied by the same manner. First, in step S310, the system is initiated and a BIOS procedure is performed. Thereafter, in step S320, the SMBIOS template data 170 is loaded and a value 1 Bh of the header length for data type 1 is obtained accordingly. In step S330, the SMBIOS data block 180 is loaded and a value 1 Bh of the header length for data type 1 is obtained accordingly. Meanwhile, the template data 170 and the data block 180 are only loaded to the memory buffer 160, but not loaded to the memory 150. In step S340, it is compared whether the header length for data type 1 in the SMBIOS template data 170 matches to that of the data block 180. In this embodiment, the header length for data type 1 in the SMBIOS template data 170 is not matched to that of the data block 180, which represents that data formats (or version) of the SMBIOS template data 170 and the data block 180 are not matched, therefore, adjustment is required. Therefore, a modification algorithm is performed to modify the data format of the data block 180 by utilizing the header length of the template data 170 and adding the shortened strings such that the data format of the data block 180 may match to that of the data format of the SMBIOS template data 170 (step S350).

FIG. 6 is a schematic showing an embodiment of data format adjustment according to the invention. As shown in FIG. 6, data formats 600 and 610 are respectively data formats before and after the data adjustment for data with data type 1 in the data block 180. The header length of the data format 600 (19 h) is not matched to that of the template data (1 Bh), i.e. two bytes shorter than the template data, such that an S1 string that has been filled to the string data field for data with data type 1 in the template data will be incomplete (for example, a portion of the S1 string may serve as a portion of the header data field). Therefore, adjustment for data format is required to modify the header length field from the value 19 h to 1 Bh, add two bytes of a default header data, and add two default strings 614 subsequent to a S2 string in the string data field, as shown in data format 610. Note that the default header data has to follow a defined format for the template data 170 and the default string may be an empty string for allowing future updating of data to be filled in. It is to be noted that modification is only applied to data loaded to the memory buffer 160, and data in the corresponding SMBIOS data block 180 in the flash memory is unchanged.

After the data format modification in step S350 has been completed, data format of the loaded SMBIOS data block 180 has been changed to a data format that matches to the data format of the SMBIOS template data 170. Therefore, by using the SMBIOS template data 170 and data in the adjusted SMBIOS data block 180, the header data field and the string data field for data with data type 1 in the adjusted SMBIOS data block 180 can be properly filled to the corresponding header data field and string data field for data with data type 1 in the SMBIOS template data 170 so as to generate correct SMBIOS related information (step S360). Steps S340 to S360 may be applied to any kind of data types and after all data types have been applied, the final SMBIOS related information generated can be loaded or stored in the memory. After the final SMBIOS related information has been loaded in the memory, the BIOS procedure is completed and then the operating system can be activated such that the SMBIOS related information can be provided for use by the operating system (step S370).

Moreover, after the operating system has been successfully loaded, a tool pro gram that is used for collecting and modifying the SMBIOS data may be utilized to modify the default value and the default string filled by the modification algorithm to correct values or strings such that flexibility is offered. When the data format of the SMBIOS data block 180 has also been updated to a new format, the modification algorithm may be ignored while the comparing step and the SMBIOS template data 170 and data in the SMBIOS data block 180 may be directly utilized to generate SMBIOS related information so as to acquire various configurations of the system.

In summary, according to the data processing method and processing apparatus using the same of the invention, by comparing a same reference value in two different data, whether the data formats of the two data are not matched can be determined before the two data is loaded to the memory and once the two data are not matched, a modification algorithm can be performed to adjust and modify the data formats to generate correct data and store the correct data to the memory such that correct data will be loaded to the memory for further query. The data processing method and processing apparatus using the same of the invention significantly improves data consistency and protects system information from being lost. Further, the data processing method and processing apparatus using the same of the invention can also be applied in a production line.

It is to be noted that, although the SMBIOS format is illustrated as an example in the embodiments, as one skilled in the art will appreciate, the invention may also be applied to any other type of data formats.

Processing apparatuses and data processing methods thereof, or certain aspects or portions thereof, may take the form of a program code (i.e., executable instructions) embodied in tangible media, such as floppy diskettes, CD-ROMS, hard drives, or any other machine-readable storage medium, wherein, when the program code is loaded to and executed by a machine, such as a computer, the machine thereby becomes an apparatus for practicing the methods. The methods may also be embodied in the form of a program code transmitted over some transmission medium, such as electrical wiring or cabling, through fiber optics, or via any other form of transmission, wherein, when the program code is received and loaded to and executed by a machine, such as a computer, the machine becomes an apparatus for practicing the disclosed methods. When implemented on a general-purpose processor, the program code combines with the processor to provide a unique apparatus that operates analogously to application specific logic circuits.

Certain terms are used throughout the description and claims to refer to particular system components. As one skilled in the art will appreciate, consumer electronic equipment manufacturers may refer to a component by different names. This document does not intend to distinguish between components that differ in name but not function.

While the invention has been described by way of example and in terms of preferred embodiment, it is to be understood that the invention is not limited thereto. To the contrary, it is intended to cover various modifications and similar arrangements (as would be apparent to the skilled in the art). Therefore, the scope of the appended claims should be accorded to the broadest interpretation so as to encompass all such modifications and similar arrangements.

What is claimed is:

1. A data processing method for loading data from a non volatile memory to a memory comprising:
loading a template data in the non volatile memory;
loading a data block corresponding to the template data in the non volatile memory;
comparing whether a first reference value of the template data matches to a second reference value of the data block;
performing a modification algorithm to adjust the data format of the loaded data block based on the first reference value of the template data when the first reference value does not match to the second reference value; and
generating system related information and storing the system related information to the memory according to the template data and the adjusted data block adjusted by the modification algorithm.

2. The data processing method as claimed in claim 1, wherein the step of comparing whether a first reference value of the template data matches to a second reference value of the data block further comprises:
comparing whether the header length of the template data matches to that of the data block.

3. The data processing method as claimed in claim 1, wherein the step of generating system related information further comprises:
filling data in the adjusted data block to the corresponding position of the corresponding block of the template data to generate the system related information.

4. The data processing method as claimed in claim 1, wherein the step of adjusting the data format of the loaded data block based on the first reference value of the template data further comprises:
adjusting the header length of the data block according to the first reference value of the template data; and
adding corresponding default header data and default string to the data block.

5. The data processing method as claimed in claim 4, further comprising:
modifying the corresponding default header data and default string utilizing a utility program.

6. The data processing method as claimed in claim 1, further comprising:
updating the data block in the non volatile memory; and
generating the system related data information according to the data in the updated data block and the template data.

7. The data processing method as claimed in claim 1, wherein the template data is a template data of the system management basic input/out system (SMBIOS) and the data block is a data block of the SMBIOS.

8. The data processing method as claimed in claim 1, wherein the memory is a dynamic memory.

9. The data processing method as claimed in claim 1, wherein the data formats of the template data and the data block at least comprises a type field, a header length field, a header data field and a string data field.

10. The data processing method as claimed in claim 9, wherein the step of generating system related information further comprises:
filling data in the header data field and the string data field of the data block to a corresponding header data field and the string data field of the data block of the template data.

11. A processing apparatus, comprising:
a non volatile memory, having a template data and a data block corresponding to the template data;
a memory;
a loading module, loading the template data and the data block from the non volatile memory;
a correction module, comparing whether a reference value of the template data matches to a corresponding reference value of the data block and performing a modification algorithm to adjust the data format of the loaded data block based on the first reference value of the template data when the reference value does not match to the corresponding reference value; and
a processing unit, generating system related information and storing the system related information to the memory according to the template data and the adjusted data block.

12. The processing apparatus as claimed in claim 11, further comprising a memory buffer for storing the template data and the data block loaded by the loading module.

13. The processing apparatus as claimed in claim 12, wherein the correction module further compares whether the reference value of the template data matches to the corresponding reference value of the data block in the memory buffer.

14. The processing apparatus as claimed in claim 12, wherein the correction module further compares whether the header length of the template data matches to that of the data block in the memory buffer.

15. The processing apparatus as claimed in claim 11, wherein the template data is a template data of the system management basic input/out system (SMBIOS) and the data block is a data block of the SMBIOS.

16. The processing apparatus as claimed in claim 11, wherein the memory is a dynamic memory.

17. The processing apparatus as claimed in claim 11, wherein the data formats of the template data and the data block at least comprises a type field, a header length field, a header data field and a string data field.

18. The data processing method as claimed in claim 9, wherein the processing unit further fills data in the header data field and the string data field of the data block to a corresponding header data field and string data field of the data block of the template data to generate the system related information.

19. The processing apparatus as claimed in claim 11, wherein the step of performing the modification algorithm by the correction module further comprises the steps of:
adjusting the header length of the data block according to the reference value of the template data; and
adding corresponding default header data and default string to the data block.

20. The processing apparatus as claimed in claim 19, wherein the processing unit further modifies the corresponding default header data and default string utilizing a utility program after the system related information has been generated.
